(19) United States
(12) Patent Application Publication
(10) Pub. No.: US 2018/0013026 A1
(43) Pub. Date: Jan. 11, 2018

(54) SOLAR BATTERY MODULE AND METHOD FOR PRODUCING SAME

(71) Applicant: Kaneka Corporation, Osaka (JP)

(72) Inventors: Masafumi Hiraishi, Osaka (JP); Fumika Fukagawa, Osaka (JP); Toru Terashita, Osaka (JP)

(73) Assignee: Kaneka Corporation, Osaka (JP)

(21) Appl. No.: 15/710,318

(22) Filed: Sep. 20, 2017

Related U.S. Application Data
(63) Continuation of application No. PCT/JP2016/059478, filed on Mar. 24, 2016.

(30) Foreign Application Priority Data
Mar. 26, 2015 (JP) 2015-064108

(51) Int. Cl. H01L 31/05; H01L 31/048; H01L 31/18; H01L 31/049; H01L 31/0224

(52) U.S. Cl. CPC H01L 31/0516; H01L 31/18; H01L 31/049; H01L 31/0481; H01L 31/022425

(57) ABSTRACT

A solar cell module includes a solar cell, a wiring member electrically connected to the solar cell, a light-receiving-surface encapsulant and a back-surface encapsulant that cover the solar cell, a light-receiving-surface protecting member; and a back-surface protecting member. The back-surface protecting member does not contain a metal foil. A back-side metal electrode contacts the back-surface encapsulant. The arithmetic mean roughness of the surface of the back-side metal electrode that contacts the back-surface encapsulant is less than 0.1 μm. The back-surface encapsulant comprises a crosslinked olefin resin.

### TECHNICAL FIELD

The present invention relates to a solar cell module and a method for producing the same.

### BACKGROUND ART

A solar cell module has a configuration in which a plurality of solar cells (hereinafter, the solar cell is referred to simply as a “cell”) electrically connected in series or in parallel by a connection member is encapsulated between a light-receiving-surface protecting member such as a glass plate and a back-surface protecting member (back sheet). Encapsulation of the cell is performed by disposing an encapsulant composed of a resin such as EVA (ethylene-vinyl acetate copolymer) between the cell and light-receiving-surface protecting member and the back sheet (e.g., Patent Document 1).

A solar cell module (hereinafter, referred to simply as a “module”) is required to have high moisture resistance because it is continuously used outdoors for a long period of time. Thus, a laminated film in which a metal foil of aluminum etc. is sandwiched between resin layers has been used as a back-surface protecting member. Use of a back sheet including a metal foil may cause an insulation failure, and therefore a metal foil-free back sheet is used in recent years.

A metal electrode is provided on a surface of a cell, and the metal electrode and a connection member are connected to each other by an electroconductive adhesive or solder. For effectively collecting photocarriers, it is necessary to reduce resistance by increasing the thickness of the metal electrode on the cell surface. For increasing the thickness of the electrode, a silver paste is widely used as a material of the metal electrode. A method has been suggested in which a metal electrode composed of copper etc. is formed by electroplating for reducing the cost of an electrode material and reducing resistance.

It is pointed out that a metal electrode formed by a plating method has lower adhesion with a wiring member as compared to a metal electrode formed using a silver paste. Patent Document 2 suggests that by performing electroplating at a high current density, irregularities on an electrode surface are made larger to improve adhesion between a metal electrode and a wiring member via an electroconductive adhesive.

### PRIOR ART DOCUMENTS

### Patent Documents

Patent Document 1: International Publication No. WO 2013/121549

Patent Document 2: Japanese Patent Laid-open Publication No. 2011-204955

### SUMMARY OF THE INVENTION

### Problems to be Solved by the Invention

When irregularities are provided on a surface of a plating metal electrode as suggested in Patent Document 2, contact resistance tends to increase because the contact area between a metal electrode and a wiring member decreases. When electroplating is performed at a high current density for providing surface irregularities, the volume resistance of the metal electrode increases. Thus, when the metal electrode has large surface irregularities, the fill factor (FF) of a module tends to decrease. Although a metal electrode having surface irregularities has high adhesion with a wiring member when an electroconductive adhesive is used, studies by the present inventors have shown that the metal electrode having surface irregularities tends to have low adhesion with a wiring member when a solder is used, leading to deterioration of module conversion efficiency after a temperature cycle test.

On the other hand, when the metal electrode has small surface irregularities, adhesion between the metal electrode (a portion to which the wiring member is not connected) and an encapsulant tends to be low, leading to deterioration of conversion efficiency after a moisture resistance test, and this tendency is noticeable particularly when a metal foil-free back sheet is used.

Thus, a cell including a plating metal electrode apparently has the problem that it is not easy to attain both adhesion between a metal electrode and a wiring member and adhesion between the metal electrode and an encapsulant, and thus a module does not have sufficient long-term reliability. In view of the situations described above, an object of the present invention is to provide a solar cell module having excellent long-term reliability

### Means for Solving the Problems

When a metal electrode provided on the back surface of a cell has small surface roughness, and a back-surface encapsulant containing a crosslinked olefin resin is disposed in contact with a back-side metal electrode, a module having excellent long-term reliability is obtained even when a metal foil-free back sheet is used.

A solar cell module according to the present invention includes: a solar cell; a wiring member electrically connected to the solar cell; an encapsulant covering the solar cell; a light-receiving-surface protecting member provided on the light-receiving-side of the solar cell; and a back-surface protecting member provided on the back side of the solar cell.

The back-surface protecting member does not contain a metal foil.

The solar cell includes a photoelectric conversion section, and a back-side metal electrode provided on the back surface of the photoelectric conversion section. In one embodiment, the photoelectric conversion section includes a first conductive silicon-based thin-film and a light-receiving-side transparent electroconductive layer on the light-receiving-side of a single-crystalline silicon substrate, and includes a second conductive silicon-based thin-film and a back-side transparent electroconductive layer on the back side of the single-crystalline silicon substrate.

The back-side metal electrode may be provided over the entire back surface of the photoelectric conversion section, or provided in a pattern such as a grid shape. The back-side metal electrode includes a principal electroconductive layer composed of copper etc. Preferably, the principal electroconductive layer is formed by a plating method. The solar cell may include a light-receiving-surface electrode on the light-receiving surface of the photoelectric conversion section.

The encapsulant includes a light-receiving-surface encapsulant provided between the solar cell and the light-receiving-surface protecting member, and a back-surface encapsulant provided between the solar cell and the back-surface protecting member. The back-surface encapsulant contains a crosslinked olefin resin. The gel fraction of the back-surface encapsulant is preferably 50% or more. Preferably, the light-receiving-surface encapsulant also contains a crosslinked olefin resin.

The back-surface encapsulant is in contact with the back-side metal electrode of the solar cell. The arithmetic mean roughness of a surface of the back-side metal electrode, which is in contact with the back-surface encapsulant, is less than 0.1 μm. The bonding strength between the back-surface encapsulant and the back-side metal electrode at 85° C. is preferably 15 N/cm or more.

### Effects of the Invention

According to the present invention, there is provided a solar cell module which has small contact resistance between a back-side metal electrode and a wiring member and which is excellent in reliability such as moisture resistance.

### BRIEF DESCRIPTION OF THE DRAWINGS

FIG. 1 is a schematic sectional view showing a solar cell module structure according to one embodiment.

FIG. 2 is a schematic sectional view showing a solar cell according to one embodiment.

### DESCRIPTION OF EMBODIMENTS

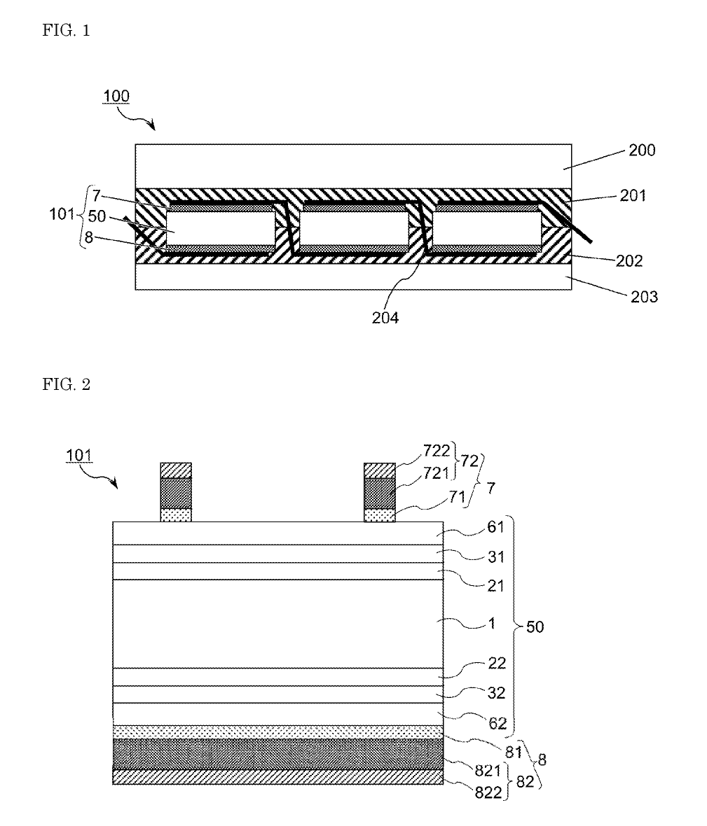

As schematically shown in FIG. 1, a module 100 includes a plurality of cells 101; a wiring member 204 that electrically connects the cells; encapsulants 201 and 202 covering the light-receiving surface and the back surface of each of the cells; a light-receiving-surface protecting member 200 provided on the light-receiving-side; and a back-surface protecting member 203 provided on the back side.

The cell 101 includes a back-side metal electrode on the back surface of a photoelectric conversion section 50. In the embodiment shown in FIG. 1, a light-receiving-surface electrode 7 is provided on the light-receiving surface of the photoelectric conversion section 50. In a back contact-type cell including a p-type semiconductor layer and an n-type semiconductor layer on the back side of a photoelectric conversion section, the light-receiving surface of the photoelectric conversion section is not provided with an electrode, and only the back surface of the photoelectric conversion section is provided with an electrode.

<Configuration of Cell>

The configuration of the cell 101 is not particularly limited, and is applicable to various kinds of solar cells such as crystalline silicon solar cells, solar cells including a semiconductor substrate made of a semiconductor other than silicon, such as GaAs, silicon-based thin-film solar cells with a transparent electrode layer formed on a pin junction or a pn junction of an amorphous silicon-based thin-film or a crystalline silicon-based thin-film, compound semiconductor solar cells including CIS, CIGS or the like, dye-sensitized solar cells, and organic thin-film solar cells including an electroconductive polymer etc.

FIG. 2 is a schematic sectional view showing one embodiment of a cell. The cell 101 shown in FIG. 2 includes so called a heterojunction cell, which includes an intrinsic silicon-based thin-film 21, a first conductive silicon-based thin-film 31 and a light-receiving-surface transparent electroconductive layer 61 in this order on the light-receiving-side of the single-crystalline silicon substrate 1, and an intrinsic silicon-based thin-film 22, a second conductive silicon-based thin-film 32 and a back-side transparent electroconductive layer 62 in this order on the back side of the single-crystalline silicon substrate 1. The first conductive silicon-based thin-film 31 and the second conductive silicon-based thin-film 32 have different conductivity-types, where one of the conductive silicon-based thin-films is p-type, and the other is n-type.

As intrinsic silicon-based thin-films 21 and 22 and conductive silicon-based thin-films 31 and 32, amorphous silicon thin-films, microcrystalline silicon thin-films (thin-films containing amorphous silicon and crystalline silicon), and the like may be used. Among them, amorphous silicon thin-films are preferable. These silicon-based thin-films can be formed by, for example, a plasma-enhanced CVD method. As p-type and n-type dopant gases for formation of conductive silicon-based thin-films 31 and 32, B₂H₆ and PH₃ are preferably used.

For transparent electroconductive layers 61 and 62, for example, transparent conductive metal oxides such as indium oxide, tin oxide, zinc oxide, titanium oxide and composite oxides thereof are used. Among them, indium-based composite oxides mainly composed of indium oxide are preferable, and indium-based composite oxides mainly composed of indium tin oxide (ITO) are more preferable. The term “mainly composed of A” means that the content of A is 51% by weight or more, preferably 80% by weight or more, more preferably 90% by weight or more.

(Back-Side Metal Electrode)

A back-side metal electrode 8 is provided on the back surface of the photoelectric conversion section 50 (on the back-side transparent electroconductive layer 62 in FIG. 2). The arithmetic mean roughness Ra of a surface of the back-side metal electrode 8 is less than 0.1 μm. When the back-side metal electrode has a small arithmetic mean roughness Ra, and is thus smooth, the contact area between the back-side metal electrode and the wiring member 204 is large, and therefore contact resistance of a module can be reduced. When the back-side metal electrode 8 has a smooth surface, adhesion of connecting the wiring member 204 on the back-side metal electrode with a solder therebetween tends to increase. Thus, a module with high durability is obtained in which a wiring member is hardly peeled off even when the module is placed in an environment with a large temperature change.

The back-side metal electrode 8 may have a single layer, or a plurality of stacked layers. FIG. 2 illustrates an embodiment in which the back-side metal electrode 8 is provided over the entire back surface of the photoelectric conversion section 50, wherein the back-side metal electrode 8 includes an underlying electrode layer 81, and thereon a plating electrode layer 82 consisting of a principal electroconductive layer 821 and an electroconductive protecting layer 822.

When the back-side metal electrode is formed on the entire back surface of the photoelectric conversion section, prevention of ingress of moisture into the cell can be expected. A region that is not provided with the back-side metal electrode may exist on a part of the peripheral edge etc. of the cell for the purpose of e.g., eliminating a short-circuit. When the back-side metal electrode is provided on a region occupying approximately 90% or more of the back surface area of the photoelectric conversion section, the back-side metal electrode may be considered as being formed on the entire surface of the photoelectric conversion section. For ensuring that ingress of moisture can be reliably prevented, the back electrode-formed area is preferably 95% or more, especially preferably 100% of the area of the photoelectric conversion section.

The back-side metal electrode may be formed in a pattern shape. When a transparent material is used as the back-surface protecting member 203 in the module and the back-side metal electrode is formed in a pattern shape such as a grid shape, light can be captured from the back side of the cell as well. The pattern of the back-side metal electrode is preferably a grid-shaped pattern including a bus bar electrode and a finger electrode perpendicular to the bus bar electrode. Preferably, the number of finger electrodes in the back-side metal electrode is determined in view of reducing series resistance at the time when current pass through the back-side metal electrode and the back-side transparent electroconductive layer. Consequently, the number of fingers in the back-side metal electrode is preferably about two to three times as large as the number of fingers in the light-receiving-surface electrode.

Examples of the method for forming the back-side metal electrode include a physical vapor deposition (PVD) method such as a sputtering method, a chemical vapor deposition (CVD) method, and a plating method. When the back-side metal electrode includes a plurality of layers, the layers may be formed by different deposition methods. When the back-side metal electrode 8 includes the underlying electrode layer 81, the principal electroconductive layer 821 and the electroconductive protecting layer 822 as shown in FIG. 2, it is preferable that the underlying electrode layer is formed by a sputtering method or electroless plating, and the principal electroconductive layer and the electroconductive protecting layer are formed by electroplating.

The underlying electrode layer 81 is an electroconductive underlay for formation of the plating electrode layer 82 by electroplating, and a material having high conductivity and chemical stability is desirable for the underlying electrode layer 81. Examples of the material include silver, gold and aluminum. Although the method for forming the underlying electrode layer is not particularly limited, it is preferable that the underlying electrode layer is formed so as to have a smooth surface. When underlying electrode layer has a smooth surface, the plating electrode layer 82 formed thereon is also smooth, so that a back-side metal electrode having an arithmetic mean surface Ha of less than 0.1 μm can be formed.

The underlying electrode layer may be formed using an electroconductive paste such a s a silver paste, but irregularities are easily formed on the surface since the electroconductive paste contains metal particles. For making the surface irregularities of the underlying electrode layer smaller, the underlying electrode layer is formed preferably by a sputtering method or an electroless plating method as described above, especially preferably by a sputtering method. When the back-side transparent electroconductive layer is formed by a sputtering method, the back-side transparent electroconductive layer 62 and the underlying electrode layer 81 may be continuously formed.

The material of the plating electrode layer 82 is preferably aluminum, copper or the like from the viewpoint of cost reduction. Among them, copper is more preferable from the viewpoint of a conductivity. When the plating electrode layer 82 includes the electroconductive protecting layer 822 as an outermost layer provided on the principal electroconductive layer 821 composed of copper or the like, oxidation of copper in the principal electroconductive layer 821, diffusion of copper to the encapsulant, and so on can be suppressed. For ensuring that oxidation of a metal that forms the principal electroconductive layer, diffusion of the metal to the encapsulant, and so on can be reliably prevented, it is preferable that the electroconductive protecting layer is provided so as to cover the principal electroconductive layer.

The material of the electroconductive protecting layer 822 preferably has chemical stability higher than that of the principal electroconductive layer. For example, when the principal electroconductive layer is made of copper, the metallic material of the electroconductive protecting layer is preferably tin, silver or the like, particularly preferable a material mainly composed of tin. Examples of the material mainly composed of tin include alloy metals such as Sn—Ag—Cu-based alloys, Sn—Cu-based alloys and Sn—Bi-based alloys as well as pure tin.

When on copper as a principal electroconductive layer, tin is deposited as an electroconductive protecting layer, an alloy layer may be formed in the vicinity of the interface (e.g., in a region of 3 μm or less from the interface) between both the layers. When an alloy layer is formed in the vicinity of the interface between the principal electroconductive layer and the electroconductive protecting layer, chemical protection property for the principal electroconductive layer tends to be improved, but defects may be generated in the alloy layer portion, leading to formation of an ingress path of moisture. In the present invention, by using a crosslinked olefin resin as a back-surface encapsulant as described later, ingress of moisture is suppressed even when an alloy layer is formed, so that a module having excellent reliability is obtained.

When a copper layer is formed as the principal electroconductive layer 821 in the plating electrode layer 82 by electroplating, for example, an acidic copper plating solution can be used as a plating solution. By feeding a current of about 10 mA/cm² to 500 mA/cm² through the plating solution, a copper plating layer can be deposited on the underlying electrode layer. The suitable plating time is appropriately set according to the area of the electrode, the current, the cathode current efficiency, the thickness, and so on. By changing the current density, the metal deposition rate or film quality (surface irregularities) can be adjusted. As the current density increases, the metal deposition rate increases, so that irregularities tend to be easily formed on the surface. The current density is preferably 10 mA/cm² to 100 mA/cm² for forming a back-side metal electrode having a small arithmetic mean roughness Ha and low resistance.

When the electroconductive protecting layer 822 is formed on the principal electroconductive layer 821, it is preferable to form the electroconductive protecting layer by an electroplating method. When a tin layer is formed as the electroconductive protecting layer by electroplating, it is preferable to use a plating solution containing tin methanesulfonate etc., and by feeding a current of about 0.1 mA/cm² to 50 mA/cm² through the plating solution, tin can be deposited as an electroconductive protecting layer.

The thickness of the back-side metal electrode may be appropriately set according to the materials of the layers, and so on. When the back-side metal electrode is formed over the entire surface of the photoelectric conversion section, the thickness of the back-side metal electrode is, for example, preferably 1200 to 6000 nm for reducing resistance. When the back-side metal electrode 8 includes the underlying electroconductive layer 81, and the principal electroconductive layer 821 and the electroconductive protecting layer 822 formed thereon by plating the thickness of the underlying electrode layer may be about 8 to 100 nm, the thickness of the principal electroconductive layer may be about 200 to 1000 nm, and the thickness of the electroconductive protecting layer may be about 1000 to 5000 nm.

When the plating electrode layer in a pattern shape is formed by electroplating, a patterning method such as photolithography may be employed. For example, after a metal electrode layer is formed over the entire surface, a resist is then provided on the plating metal electrode layer, and the resist is light exposed so that a resist opening is formed on portions other than an electrode pattern, and the metal electrode layer is then etched away, whereby a back-side metal electrode can be formed in a pattern shape. Alternatively, the underlying electrode layer 81 may be formed over the entire back surface of the photoelectric conversion section by a sputtering method or an electroless plating method, followed by providing a resist on the underlying electrode layer 81 and the resist is light exposed so that a resist opening is formed on portions other than an electrode pattern portion, so that a plating metal electrode is selectively deposited on the opening section. It is preferable that after formation of the plating electrode, a resist is stripped, and the underlying electrode layer exposed between plating electrodes is etched away.

(Light-Receiving-Surface Electrode)

The light-receiving-surface electrode 7 may be formed in a pattern shape on the light-receiving surface of the photoelectric conversion section 50 (on the transparent electroconductive layer 61 in FIG. 2). The electrode material of the light-receiving-surface electrode 7 is not particularly limited, and metals such as gold, silver, copper and aluminum may be used. Silver or copper is preferable from the viewpoint of an electric conductivity. For example, it is preferable that a surface of the light-receiving-surface electrode mainly composed of copper is provided with a light-receiving-side electroconductive protecting layer as an outermost surface layer for suppressing oxidation of copper and diffusion of copper to the encapsulant. As a material of the light-receiving-side electroconductive protecting layer, silver, titanium, tin, chromium and the like are preferable because they have high chemical stability.

The light-receiving-surface electrode 7 can be formed by an inkjet method, a screen printing method, a wire bonding method, a spraying method, a vacuum deposition method, a sputtering method or the like. When a part or the entire of the back-side metal electrode 8 is formed by a plating method, it is preferable that a part or the entire of the light-receiving-surface electrode 7 is formed by a plating method from the viewpoint of productivity. When both the back-side metal electrode and the light-receiving-surface electrode are formed by a plating method, it is more preferable that the front and back surfaces are simultaneously plated using the same material for forming both the electrodes. For example, when as the plating electrode layer 82 for the back-side metal electrode 8, the principal electroconductive layer 821 mainly composed of copper and the electroconductive protecting layer 822 mainly composed of tin are formed on the underlying electrode layer 81, it is preferable that as the plating electrode layer 72 for the light-receiving-surface electrode 7, the principal electroconductive layer 721 mainly composed of copper and the electroconductive protecting layer 722 mainly composed of tin are formed on the underlying electrode layer 71.

The influence of surface roughness of the light-receiving-surface electrode 7 is smaller as compared to that on the back side. Thus, the arithmetic mean roughness Ra of the light-receiving-surface electrode 7 may be 0.1 μm or more, and a silver paste etc. may be used for the underlying electrode layer 71. The arithmetic mean roughness Ra of the light-receiving-surface electrode 7 is preferably less than 0.1 μm for improving adhesion between the light-receiving-surface electrode 7 and the wiring member 204, and further improving durability to a temperature change.

<Solar Cell Module>

In modularization of cells, a solar cell string with a plurality of cells connected in series or in parallel is prepared. Adjacent cells are connected by bonding the wiring member 204 to the light-receiving-surface electrode 7 and the back-side metal electrode 8. The light-receiving-surface encapsulant 201 and the back-surface encapsulant 202 are disposed in contact with the light-receiving surface and the back surface, respectively, of the solar cell string, and the light-receiving-surface protecting member 200 and the back-surface protecting member 203 are disposed on the outside of the light-receiving-surface encapsulant 201 and the back-surface encapsulant 202, respectively. Thereafter, pressing or the like is performed, so that the encapsulant flows to a gap between adjacent cells and the end of the module to perform encapsulation.

The wiring member 204 is an electroconductive plate-shaped member for connecting cells or a cell and an external circuit. The wiring member 204 has flexibility. As a material of the wiring member, copper is generally used. A surface of a core material of copper or the like may be covered with a covering material. A surface of the wiring member may be covered with a solder for facilitating connection of a cell to an electrode. Connection of the wiring member to the cell is performed by soldering, or bonding with a resin adhesive containing electroconductive fine particles. When an electrode having small surface roughness is connected to the wiring member by a solder, adhesion tends to be improved, leading to a decrease in contact resistance.

(Protecting Member)

Examples of the light-receiving-surface protecting member 200 disposed on the light-receiving side of a cell include glass substrates (blue glass substrates and white glass substrates), and resin films such as fluororesin films such as polyvinyl fluoride films (e.g., TEDLAR FILM (registered trademark)), and polyethylene terephthalate (PET) films. From the viewpoint of strength, light transmittance, moisture barrier property and so on, glass substrates are preferable, and particular white glass substrates are preferable.

When a rigid member such as glass is used as the light-receiving-surface protecting member 200, a flexible film material (back sheet) is used as the back-surface protecting member 203 from the viewpoint of ease of encapsulation, and so on. A back sheet obtained by sandwiching a metal foil of aluminum or the like between resin layers has been widely used heretofore because a resin film has higher moisture permeability as compared to glass etc. A back sheet including a metal foil is apt to cause a failure such as an insulation failure.

In the module according to the present invention, a short-circuit etc. caused by a back-surface protecting member can be prevented because the back-surface protecting member 203 that does not include a metal foil is used. As the back-surface protecting member, a fluororesin film such as a polyvinyl fluoride film (e.g., TEDLAR FILM (registered trademark)), a polyethylene terephthalate (PET) film, or the like is used. The back-surface protecting member may have a single layer, or may have a structure in which a plurality of films is stacked. Use of a single-layer film of PET etc. is more preferable for reducing production costs.

(Encapsulant)

The back-surface encapsulant 202 provided in contact with the back side of the cell 101 contains a crosslinked olefin resin. The “crosslinkable olefin resin” can be crosslinked when heated. The crosslinkable olefin resin retains its shape without being softened when held at 80° C. to 150° C. after being crosslink-cured. The “crosslinked olefin resin” is obtained by crosslink-curing the “crosslinkable olefin resin”. A “dynamically crosslinkable olefin-based thermoplastic elastomer” which is fluidized at 80° C. or higher, such as olefin-based TPV, does not belong to the crosslinkable olefin resin.

Examples of the olefin resin include chain polyolefins such as high-density polyethylene (HDPE), high-pressure low-density polyethylene (LDPE), linear low-density polyethylene (LLDPE) and polypropylene (PP) ethylene•α-olefin copolymers, and cyclic polyolefins such as monocyclic olefin polymers and norbornene-based polymers. The crosslinkable olefin resin composition is preferably a thermally crosslinkable olefin resin composition which is mainly composed of any of the above-mentioned olefin resins and further contains a thermal radical generator such as an organic peroxide, and a thermal crosslinking agent.

The crosslinked state (cured state) of the crosslinked olefin resin can be checked by a gel fraction. The gel fraction is a mass fraction of insolubles after the olefin resin after curing is immersed in xylene at 120° C. for 24 hours. The gel fraction of the crosslinked olefin resin after curing is preferably 50% or more, more preferably 70% or more, further preferably 80% or more. When the gel fraction falls within the above-mentioned range, improvement of reliability can be expected.

The water vapor transmission rate of the back-surface encapsulant 202 after curing is preferably 3.0 [g/m²/day] or less, more preferably 2.6 [g/m²/day] or less, further preferably 1.5 [g/m²/day] or less. By using a back-surface encapsulant having a low water vapor transmission rate, ingress of moisture into a cell can be more reliably prevented, so that long-term reliability of the module can be improved.

In the present invention, adhesion between the back-side metal electrode 8 and a wiring member 402 is improved because the back-side metal electrode 8 in the cell has a smooth surface as described above. In a region that is not connected to the wiring member, like a finger electrode section of a grid-shaped electrode, the back-side metal electrode 8 and the back-surface encapsulant 202 are in contact with each other. When the surface of the back-side metal electrode 8 is smooth, and has a small arithmetic mean roughness Ha, adhesion between the back-side metal electrode 8 and the back-surface encapsulant 202 is reduced, so that ingress of moisture between the back-side metal electrode and the back-surface encapsulant tends to easily occur. This tendency is noticeable particularly when a metal foil-free resin sheet is used as the back-surface protecting member 203. When an alloy layer is formed in the vicinity of the interface between the principal electroconductive layer of the back-side metal electrode and the electroconductive protecting layer as described above, ingress of moisture through defective portions of the alloy layer may occur.

EVA that is generally used as an encapsulant easily releases acetic acid when coming into contact with moisture. The free acid causes corrosion of the back-side metal electrode. Therefore, in a module with an EVA encapsulant disposed in contact with a back-side metal electrode having a small arithmetic mean roughness Ha, deterioration of conversion characteristics occurs in a long-term reliability test (particularly moisture resistance test). When a non-crosslinked olefin is used, the resin is easily softened at a high temperature of 80° C. or higher, and thus adhesion with the back-side metal electrode is further reduced, so that ingress of moisture tends to easily occur.

On the other hand, when a crosslinked olefin is used as the back-surface encapsulant, the encapsulant is hardly fluidized even in a high-temperature environment, so that bonding strength between the back-surface encapsulant and the back-side metal electrode is maintained (rather bonding strength tends to increase), and therefore ingress of moisture into a cell can be suppressed. Thus, according to the present invention, a module having excellent moisture resistance is obtained although the back-surface protecting member does not include a metal foil.

In the module according to the present invention, the back-side metal electrode has a smooth surface as described above, and therefore contact resistance between the back-side metal electrode and the wiring member is small, so that the power generation of the module can be improved. Even if a temperature change occurs, the wiring member is hardly peeled from the back-side metal electrode, and thus excellent durability is attained. The back-side metal electrode having a smooth surface and the crosslinked olefin encapsulant are combined with each other to suppress ingress of moisture, so that moisture resistance is improved. As explained heretofore, a module having improved conversion efficiency due to reduction of contact resistance and improved long-term durability can be provided according to the present invention.

For preventing ingress of moisture to improve long-term reliability, the bonding strength between the back-surface encapsulant and the back-side metal electrode at 85° C. is preferably 15 N/cm or more, more preferably 20 N/cm or more, further preferably 30 N/cm or more. For preventing ingress of moisture, the bonding strength is preferably as high as possible, and the upper limit of the bonding strength is not particularly limited. Generally, the bonding strength between the back-surface encapsulant and the back-side metal electrode at 85° C. is 200 N/cm or less.

Since an amorphous semiconductor layer such as an amorphous silicon thin-film is easily degraded when exposed to moisture, a cell including an amorphous semiconductor layer such as heterojunction solar cell often has poor long-term reliability. On the other hand, by using a crosslinked olefin resin as the back-surface encapsulant, ingress of moisture into a cell can be suppressed to improve long-term reliability even when a metal foil-free back-surface protecting member is used.

By using a crosslinked olefin resin as the back-surface encapsulant, ingress of moisture into a cell can be suppressed to improve long-term reliability even when an alloy layer is formed between the principal electroconductive layer and the electroconductive protecting layer in the back-side metal electrode. Thus, when a crosslinked olefin resin is used as the back-surface encapsulant that is in contact with the electroconductive protecting layer in the back-side metal electrode, ingress of moisture into a cell can be suppressed while degradation of the principal electroconductive layer by oxidation etc. and diffusion of a metal component in the principal electroconductive layer are suppressed by the electroconductive protecting layer, and therefore a module having excellent reliability is obtained.

Although the material of the light-receiving-surface encapsulant is not particularly limited, use of an olefin resin is preferable. The olefin resin may be crosslinkable or non-crosslinkable. When a crosslinkable olefin is used as in the case of the back-surface encapsulant, durability of the module tends to be further improved.

### EXAMPLES

### Example 1

### (Preparation of Heterojunction Solar Cell)

A 200 μm-thick n-type single-crystalline silicon wafer with a texture formed on front and back surfaces was introduced into a CVD device, i-type amorphous silicon was deposited in a thickness of 5 nm on a light-receiving surface by plasma-enhanced CVD, and p-type amorphous silicon was deposited in a thickness of 7 nm on the i-type amorphous silicon. Next, i-type amorphous silicon was deposited in a thickness of 6 nm on the back side of a wafer, and n-type amorphous silicon was deposited in a thickness of 4 nm on the i-type amorphous silicon. On each of a p-type amorphous silicon layer and an n-type amorphous silicon layer, indium tin oxide (ITO) was deposited as a transparent electroconductive layer in a thickness of 100 nm. In the manner described above, a photoelectric conversion section for a heterojunction solar cell was prepared.

As an underlying electrode layer, silver was deposited in a thickness of 100 nm over the entire surface of a back-side transparent electroconductive layer by a sputtering method. On a light-receiving-side transparent electroconductive layer, an Ag paste was screen-printed in a grid-shaped pattern including a finger electrode and a bus bar electrode. A silicon oxide layer was formed in a thickness of 100 nm over the entire light-receiving surface by plasma-enhanced CVD, and then annealed at 180° C. to form an opening in on an Ag paste-printed region of the insulating layer. This opening serves as an origination point for electroplating (see Examples in WO 2013/077038).

A substrate with an opening formed in an insulating layer on a light-receiving surface was put in an electrolytic copper plating bath. A plating solution was used in which the concentrations of copper sulfate pentahydrate, sulfuric acid and sodium chloride were adjusted to 120 g/l, 130 g/l and 70 mg/l, respectively, and an additive (grade: ESY-2B, ESY-H or ESY-1A manufactured by C. Uyemura & Co., Ltd.) were added. Plating was performed under the conditions of a temperature of 25° C., a current of 700 mA and a time of 7 minutes. Copper was uniformly deposited in a thickness of about 10 μm on each of the opening section of the insulating layer on the Ag paste-printed region of the light-receiving surface and the underlying layer on the back surface.

Thereafter, the substrate was put in a tin plating bath. A plating solution was used in which the concentrations of tin methanesulfonate, methanesulfonic acid and an additive were adjusted so as to attain a tin concentration of 30 g/l and a total free acid concentration of 1.0 mol/l. Plating was performed for 2 minutes under the conditions of a temperature of 40° C., and a current of 100 mA, so that tin was uniformly deposited in a thickness of about 3 μm on each of copper plating electrodes on front and back surfaces.

Thereafter, the silicon wafer on the outer peripheral section of the cell was removed by a width of 0.5 mm using a laser processing machine.

(Modularization)

A 1.5 mm-wide light diffusion tab line with 40 μm-height irregularities formed on the light-receiving side was soldered as a wiring member onto a bus bar of the light-receiving-surface electrode and a back-side metal electrode in the resulting heterojunction solar cell. Accordingly, a solar cell string in which a plurality of cells was connected in series was prepared.

A white glass plate was provided as a light-receiving-surface protecting member, a thermally crosslinkable polyolefin resin film was provided as a light-receiving-surface encapsulant and a back-surface encapsulant, and a 30 μm-thick PET single-layer film was provided as a back-surface protecting member. The light-receiving-surface protecting member, the light-receiving-surface encapsulant, the solar cell string, the back-surface encapsulant and the back-surface protecting member were placed and stacked in this order. As the thermally crosslinkable polyolefin resin, a composition including an olefin resin mainly composed of polyethylene as a principal component and further including an organic peroxide-based thermal polymerization initiator was used.

The stack was put in a vacuum laminator at a heat plate temperature of 150° C., and thermocompression bonding was carried out for 5 minutes, the solar cells were molded with an encapsulation resin, and then held at 150° C. under atmospheric pressure for 50 minutes to crosslink-cure the thermally crosslinkable polyolefin resin, thereby obtaining a module.

A thermally crosslinked polyolefin resin film thermally crosslinked under the same conditions as described above retained its shape without being softened even when heated again to 150° C. after heat curing. The resin film after heat curing was immersed in xylene at 120° C. for 24 hours, filtration was then performed using a 80-mesh wire gauze, the obtained insolubles were dried at 80° C. for 16 hours, and the mass of the insolubles was measured. The gel fraction calculated by dividing the mass of the insolubles by the mass of the resin before immersion in xylene was 98%.

### Example 2

(Preparation of Heterojunction Solar Cell)

After a photoelectric conversion section was prepared in the same manner as in Example 1, copper was deposited as an underlying electrode layer in a thickness of 100 nm over the entire surface of a back-side transparent electroconductive layer by a sputtering method. A resist was applied onto the deposited copper, and the resist is light exposed so that a resist opening in a grid-shaped pattern including a finger electrode and a bus bar electrode was formed. On the light-receiving side, the same procedure as in Example 1 was carried out, i.e., an Ag paste was screen-printed, a silicon oxide layer was formed, and then annealed to form an opening, which serves as an origination point for electroplating, in the silicon oxide layer.

The substrate was put in an electrolytic copper plating bath, and electroplating was performed in the same manner as in Example 1 to deposit an about 10 μm-thick plating copper electrode on each of the light-receiving surface and the back surface. In Example 2, tin plating on the copper plating electrode was not performed. After copper plating, the resist was stripped, and an underlying electrode layer exposed between the copper plating electrodes on the back surface was etched away.

(Modularization)

A wiring member was soldered onto the bus bar of the light-receiving-surface electrode and a bus bar of a back-side metal electrode in the resulting heterojunction solar cell to prepare a solar cell string in which a plurality of cells was connected in series. Thereafter, in the same manner as in Example 1, a module was obtained by performing encapsulation using a thermally crosslinkable polyolefin film as a light-receiving-surface encapsulant and a back-surface encapsulant.

### Example 3

Except that a non-crosslinkable thermoplastic polyolefin resin film mainly composed of polyethylene was used as a light-receiving-surface encapsulant, the same procedure as in Example 1 was carried out to prepare a module.

### Comparative Example 1

Except that a non-crosslinkable thermoplastic polyolefin resin film mainly composed of polyethylene was used as a light-receiving-surface encapsulant and a back-surface encapsulant, the same procedure as in Example 1 was carried out to prepare a solar cell module. In encapsulation, thermocompression bonding was performed by a vacuum laminator at a heat plate temperature of 150° C. for 15 minutes, and the subsequent thermal crosslinking treatment was not performed.

The non-crosslinked olefin resin film heated under the same conditions as described above was softened when heated again to 150° C. The gel fraction of the resin film was 17%.

### Comparative Example 2

(Preparation of Heterojunction Solar Cell)

A photoelectric conversion section was prepared in the same manner as in Example 1, an Ag paste was then screen-printed on each of a light-receiving-side transparent electroconductive layer and a back-side transparent electroconductive layer, a silicon oxide layer was formed, and then annealed to form an opening, which serves as an origination point for electroplating, in the silicon oxide layer. Thereafter, copper plating and tin plating were performed in the same manner as in Example 1 to form a grid-shaped metal electrode on both surfaces of the light-receiving surface and the back surface.

(Modularization)

In the same manner as in Example 2, bus bars on the light-receiving surfaces and the back surfaces of adjacent solar cells were electrically connected by a wiring member to prepare a solar cell string. In the same manner as in Comparative Example 1, a solar cell module was obtained by performing encapsulation using a thermally crosslinkable polyolefin film as a light-receiving-surface encapsulant and a back-surface encapsulant.

### Comparative Example 3

A heterojunction solar cell was prepared in the same manner as in Comparative Example 2. Thereafter, in the same manner as in Comparative Example 1, a non-crosslinkable thermoplastic polyolefin resin film mainly composed of polyethylene was used as a light-receiving-surface encapsulant and a back-surface encapsulant to perform encapsulation, thereby obtaining a module.

[Evaluation]

### (Surface Roughness of Back-Side Metal Electrode)

A surface of the back-side metal electrode before connection of the wiring member was observed with a confocal microscope H1200 manufactured by Lasertec Corporation), and the arithmetic mean roughness Ra was determined on the basis of JIS B 0601:2001 (corresponding to ISO 4287: 1997).

(Contact Resistance Between Back-Side Metal Electrode and Wiring Member)

A probe pin was brought into contact with the tops of adjacent two bus bars of the back-side metal electrode before connection of the wiring member, and the resistance R₀ between the two points was measured. After the wiring member was connected, a probe pin was brought into contact with the wiring member at the same positions as the above-mentioned two points, and the resistance R₁ between the two points was measured. In Examples 1 and 3 and Comparative Example 1 where the metal electrode was formed over the entire back surface, the resistances R₀ and R₁ before and after connection of the wiring member were measured between two points in a portion where adjacent wiring members were (scheduled to be) connected. The value of (R₀−R₁)/2 was defined as a contact resistance per one wiring member.

(Peel Strength Between Back-Side Metal Electrode and Wiring Member)

At room temperature (23° C.), the wiring member of the solar cell string before encapsulation was separated from the back-side metal electrode by drawing the wiring member in a direction of 90° using a digital force gauge, and the peel strength was measured.

(Bonding Strength Test)

For the solar cell modules prepared in Examples and Comparative Examples, the bonding strength between the back-side metal electrode and the back-surface encapsulant was measured in a 90° peeling test. A 10 mm-wide cut was made on the module back surface, the end thereof was raised, and drawn in a direction of 90° by a digital force gauge to delaminate the module, and the peel strength was measured. The measurement was performed in a room temperature (23° C.) and with the sample heated to 85° C., respectively.

(Moisture Resistance Test)

A moisture resistance test was conducted in accordance with IEC 61215. The initial power of the solar cell module was measured, and the solar cell module was then held for 1000 hours in a thermohygrostat at a temperature of 85° C. and a humidity of 85%. Thereafter, the power of the solar cell module was measured again, and the ratio of the power after 1000 hours to the initial power (retention) for the solar cell module was determined.

(Temperature Cycle Test)

A temperature cycle test was conducted in accordance with JIS C8917. After the initial power of the solar cell module was measured, the solar cell module was introduced into a test chamber, and subjected to a 200-cycle temperature cycle test. Each cycle includes a process in which the solar cell module is held at 90° C. for 10 minutes, cooled to −40° C. at a rate of 80° C./minute, held at −40° C. for 10 minutes, and heated to 90° C. at a rate of 80° C./minute. Thereafter, the power of the solar cell module was measured again, and the ratio of the power after 200 cycles to the initial power (retention) for the solar cell module was determined.

For the solar cell modules in examples and comparative examples, the configuration and the arithmetic mean roughness Ra of the back-side metal electrode, the characteristics (contact resistance and peel strength) of the interface between the back-side metal electrode and the connection member, the type of resin used in the encapsulant, the peel strength between the back-side metal electrode and the back-surface encapsulant, and the module durability test results are shown in Table 1.

TABLE 1

| | Back electrode | | | | | Back electrode/ | |
|---|---|---|---|---|---|---|---|
| | Layer configuration | | | | | wiring member | |
| | | Principal | Electroconductive | | | Contact | Peel |
| | Underlying | electroconductive | protecting | | Ra | resistance | strength |
| | layer | layer | layer | Shape | [μm] | [mΩ] | [N] |
| Example 1 | Sputtered | Plated Cu | Plated Sn | Entire | 0.07 | 0.06 | 3.5 |
| | Ag | | | surface | | | |
| Example 2 | Sputtered | Plated Cu | — | Grid | 0.08 | 0.06 | 4.7 |
| | Cu | | | | | | |
| Example 3 | Sputtered | Plated Cu | Plated Sn | Entire | 0.09 | 0.09 | 4.2 |
| | Ag | | | surface | | | |
| Comparative | Sputtered | Plated Cu | Plated Sn | Entire | 0.08 | 0.03 | 4.5 |
| Example 1 | Ag | | | surface | | | |
| Comparative | Ag paste | Plated Cu | Plated Sn | Grid | 5.2 | 0.09 | 1.1 |
| Example 2 | | | | | | | |
| Comparative | Ag paste | Plated Cu | Plated Sn | Grid | 6.1 | 0.11 | 0.9 |
| Example 3 | | | | | | | |

| | | | Back electrode/ | | | |
|---|---|---|---|---|---|---|
| | | | encapsulant | | Retention in | |
| | | | Peel strength | | module | |
| | Encapsulant | | [N/cm] | | durability test [%] | |
| | Back | Light-receiving | Room | | Moisture | Temperature |
| | surface | surface | temperature | 85° C. | resistance test | cycle test |
| Example 1 | Thermally | Thermally | 29 | 39 | 99 | 100 |
| | crosslinkable | crosslinkable | | | | |
| | olefin | olefin | | | | |
| Example 2 | Thermally | Thermally | 33 | 40 | 99 | 98 |
| | crosslinkable | crosslinkable | | | | |
| | olefin | olefin | | | | |
| Example 3 | Thermally | Non- | 32 | 39 | 98 | 100 |
| | crosslinkable | crosslinkable | | | | |
| | olefin | olefin | | | | |
| Comparative | Non- | Non- | 43 | 7 | 93 | 94 |
| Example 1 | crosslinkable | crosslinkable | | | | |
| | olefin | olefin | | | | |
| Comparative | Thermally | Thermally | 35 | 42 | 98 | 97 |
| Example 2 | crosslinkable | crosslinkable | | | | |
| | olefin | olefin | | | | |
| Comparative | Non- | Non- | 45 | 12 | 94 | 90 |
| Example 3 | crosslinkable | crosslinkable | | | | |
| | olefin | olefin | | | | |

Comparison of Examples 1 to 3 with Comparative Example 2 shows that the solar cell module of Comparative Example 2 in which the back-side metal electrode has a large arithmetic mean roughness Ra has larger peel strength (bonding strength) between the back electrode and the encapsulant as compared to the solar cell modules of Examples 1 to 3 in which the back-side metal electrode has a small arithmetic mean roughness Ra. On the other hand, the solar cell modules of Examples 1 to 3 tended to have smaller contact resistance between the back electrode and the wiring member, and larger peel strength as compared to the solar cell module of Comparative Example 2. The solar cell module of Comparative Example 2 had a lower retention after the temperature cycle test as compared to the solar cell modules of Examples 1 to 3.

These results show that by using a back-side metal electrode in which a surface that is in contact with a back-surface encapsulant has a small arithmetic mean roughness Ra, a solar cell module having low contact resistance with a wiring member, high bonding strength with the wiring member, and high temperature cycle durability is obtained.

The solar cell modules of Comparative Examples 1 and 3 using a non-crosslinkable olefin as an encapsulant are comparable to the solar cell modules of Examples 1 to 3 in peel strength between the back electrode and the encapsulant at room temperature. On the other hand, in Comparative Examples 1 and 3, the peel strength between the back electrode and the encapsulant at 85° C. was considerably reduced, whereas in Examples 1 to 3 using a crosslinkable olefin, the peel strength at 85° C. was not smaller than that at room temperature. The modules of Comparative Examples 1 and 3 had a considerably reduced retention after the moisture resistance test, whereas the modules of Examples 1 to 3 had a retention of 98% or more.

In Example 2 in which a non-crosslinkable olefin was used as a light-receiving-surface encapsulant, the retention after the moisture resistance test was 98%, slightly lower as compared to Examples 1 and 3, but the retention was comparable to that in Comparative Example 2 in which a thermally crosslinkable olefin was used for the encapsulant on both surfaces. From the results, it is considered that on the light-receiving side, a glass substrate is used as a protecting member, and therefore the light-receiving surface is less affected by ingress of moisture than the back surface, so that even when a non-crosslinkable olefin is used as a light-receiving-surface encapsulant, the retention after moisture resistance test can be kept high. Although ingress of moisture easily occurs on the back side of a module using a metal foil-free film as a as a protecting member, it is considered that ingress of moisture into a cell is blocked by using a crosslinked olefin as an encapsulant, so that high moisture resistance is attained.

As can be understood from the above, a solar cell module having low contact resistance with a wiring member and excellent initial conversion characteristics is obtained when the back-side metal electrode has a small arithmetic mean roughness Ra, and is thus smooth. When the back-side metal electrode has a small arithmetic mean roughness Ra, adhesion between the back-side metal electrode and the wiring member is high, so that temperature cycle durability of the module is improved. On the other hand, the back-side metal electrode having small arithmetic mean roughness Ra tends to cause slight reduction of bonding strength between the back-side metal electrode and the encapsulant at normal temperature. By using a thermally crosslinked olefin as a back-surface encapsulant, moisture blocking property is improved, and adhesion between the back-side metal electrode and the encapsulant can be maintained even in a high-temperature environment. Thus, moisture resistance of the module can be kept high even when the back-side metal electrode has a small arithmetic mean roughness Ra.

According to the present invention, a solar cell module having excellent initial conversion characteristics and long-term reliability is obtained even when a metal foil-free back-surface protecting member is used.

### DESCRIPTION OF REFERENCE CHARACTERS

7. light-receiving-surface electrode
71. underlying electrode layer
721. principal electroconductive layer
722. electroconductive protecting layer
8. back-side metal electrode
81. underlying electrode layer
821. principal electroconductive layer
822. electroconductive protecting layer
50. photoelectric conversion section
101. solar cell
100. solar cell module
200. light-receiving-surface protecting member
201. light-receiving-surface encapsulant
202. back-surface encapsulant
203. back-surface protecting member
204. wiring member

What is claimed is:

1. A solar cell module comprising:
a solar cell;
a wiring member electrically connected to the solar cell;
an encapsulant covering the solar cell, the encapsulant comprising a light-receiving-surface encapsulant and a back-surface encapsulant;
a light-receiving-surface protecting member provided on a light-receiving side of the solar cell; and
a back-surface protecting member provided on a back side of the solar cell,
wherein the solar cell comprises a photoelectric conversion section, and a back-side metal electrode provided on a back surface of the photoelectric conversion section,
wherein the light-receiving-surface encapsulant is provided between the solar cell and the light-receiving-surface protecting member,
wherein the back-surface encapsulant comprises a crosslinked olefin resin, and is provided between the solar cell and the back-surface protecting member,
wherein the back-surface protecting member does not comprise a metal foil,
wherein the back-side metal electrode comprises a principal electroconductive layer and a surface in contact with the back-surface encapsulant, and
wherein the surface in contact with the back-surface encapsulant has an arithmetic mean roughness of less than 0.1 μm.

2. The solar cell module according to claim 1, wherein a gel fraction of the back-surface encapsulant is 50% or more.

3. The solar cell module according to claim 1, wherein a bonding strength between the back-surface encapsulant and the back-side metal electrode at 85° C. is 15 N/cm or more.

4. The solar cell module according to claim 1, wherein the back-side metal electrode is formed on the entire back surface of the photoelectric conversion section.

5. The solar cell module according to claim 1, wherein the solar cell comprises a light-receiving-surface electrode on a light-receiving surface of the photoelectric conversion section.

6. The solar cell module according to claim 1,
wherein the back-side metal electrode further comprises an electroconductive protecting layer that is an outermost layer of the back-side metal electrode,
wherein the electroconductive protecting layer is a metal layer having chemical stability higher than that of the principal electroconductive layer, and
wherein the electroconductive protecting layer comprises the surface in contact with the back-surface encapsulant.

7. The solar cell module according to claim 6, wherein the electroconductive protecting layer comprises tin.

8. The solar cell module according to claim 6,
wherein the electroconductive protecting layer covers the principal electroconductive layer,
wherein the back-side metal electrode further comprises an alloy layer composed of materials of the principal electroconductive layer and the electroconductive protecting layer, and
wherein the alloy layer is provided at an interface between the principal electroconductive layer and the electroconductive protecting layer.

9. The solar cell module according to claim 1, wherein the principal electroconductive layer is formed of copper.

10. The solar cell module according to claim 1, wherein the light-receiving-surface encapsulant comprises a crosslinked olefin resin.

11. The solar cell module according to claim 1, wherein the photoelectric conversion section comprises:
a single-crystalline silicon substrate;
a first conductive silicon-based thin-film;
a light-receiving-side transparent electroconductive layer;
a second conductive silicon-based thin-film; and
a back-side transparent electroconductive layer,
wherein the first conductive silicon-based thin-film and the light-receiving-side transparent electroconductive layer are provided on a light-receiving side of the single-crystalline silicon substrate, and
wherein the second conductive silicon-based thin-film and the back-side transparent electroconductive layer are provided on a back side of the single-crystalline silicon substrate.

12. A solar cell module production method for producing the solar cell module according to claim 1, the method comprising forming the principal electroconductive layer of the back-side metal electrode by a plating method.

13. The solar cell module production method according to claim 12, further comprising forming an electroconductive protecting layer composed of metal having chemical stability higher than that of the principal electroconductive layer by a plating method, wherein the electroconductive protecting layer covers the principal electroconductive layer.
